(19) United States
(12) Patent Application Publication
(10) Pub. No.: US 2024/0145217 A1
(43) Pub. Date: May 2, 2024

(54) METHOD FOR FORMING HIGHLY UNIFORM DIELECTRIC FILM

(71) Applicant: Applied Materials, Inc., Santa CLara, CA (US)

(72) Inventors: Qintao Zhang, Mt. Kisco, NJ (US); Eric Jay Simmons, JR., Ballston Spa, NY (US); Jared Traynor, San Jose, CA (US); Wei Zou, Lexington, MA (US); Miguel Fung, Cupertino, CA (US); Samphy Hong, Saratoga Springs, NY (US)

(21) Appl. No.: 17/979,545

(22) Filed: Nov. 2, 2022

(51) Int. Cl. H01J 37/32

(52) U.S. Cl. CPC H01J 37/32412; H01J 2237/2001; H01J 2237/20214; H01J 2237/20221; H01J 2237/3365

(57) ABSTRACT

Methods for processing a dielectric film to improve its uniformity of thickness and refractive index are disclosed. The dielectric film is deposited using conventional approaches, such as chemical vapor deposition (CVD) or spin coating. The workpiece, with the applied dielectric film is then processed to improve the uniformity of the thickness. This processing may comprise implanting a thinning species to the thicker portions of the dielectric film to reduce the thickness of these portions. The thinning species may be silicon or another suitable species. This processing may alternatively or additionally include implanting a thickening species to the thinner portions of the dielectric film to increase their thickness. The thickening species may be helium or another suitable species. This approach may reduce the variation in thickness by 50% or more.

Embodiments of the present disclosure relate to a method of creating a highly uniform dielectric film, and more particularly a uniform film for photonic applications.

### BACKGROUND

Semiconductor workpieces are used for many applications. One such application is photonics wavelength filters. In this application, a plurality of waveguides, which appears as raised features, are created on or within a dielectric material on the top surface of the workpiece.

These waveguides may utilize different multiplexing schemes. Two such schemes may be referred to as Coarse Wavelength Division Multiplexing (CWDM) and Dense Wavelength Division Multiplexing (DWDM). In CWDM, the various wavelengths are separated by 20 nm. In DWDM, the channels are even closer, with the wavelengths separated by only 0.8 nm.

The height and width of these features have a great effect on the performance of the wavelength filter. For example, in one test, it was found that a change of 1 nanometer in feature width changes the wavelength associated with that feature of the filter by 1 nanometer. It was also found that a 1 nanometer change in the height of the feature affected the wavelength associated with that feature by 2 nanometers, indicating the criticality of this dimension.

Creating a workpiece with a uniform dielectric film using conventional techniques may be difficult. For example, spin coating and deposition often create a thicker coating near the outer edge of the workpiece. In some embodiments, the thickness of the film may vary by up to 9 nanometers across the workpiece. In other words, the thickness of the film may be 9 nanometers thicker at the edges than at the center of the workpiece.

This nonuniformity in film thickness may result in a large variation from the desired wavelength. Specifically, a 9 nanometer change in height changes the wavelength associated with that feature by 18 nanometers. This variation may be unacceptable.

Therefore, it would be beneficial if there were a method of processing the dielectric film to improve its thickness uniformity. Further, it would be advantageous if this processing also improved the uniformity of the refractive index of the dielectric film across the entirety of the workpiece.

### SUMMARY

Methods for processing a dielectric film to improve its uniformity of thickness and refractive index are disclosed. The dielectric film is deposited using conventional approaches, such as chemical vapor deposition (CVD) or spin coating. The workpiece, with the applied dielectric film, is then processed to improve the uniformity of the thickness. This processing may comprise implanting a thinning species to the thicker portions of the dielectric film to reduce the thickness of these portions. The thinning species may be silicon or another suitable species. This processing may alternatively or additionally include implanting a thickening species to the thinner portions of the dielectric film to increase their thickness. The thickening species may be helium or another suitable species. This approach may reduce the variation in thickness by 50% or more.

According to one embodiment, a method of adjusting a thickness of a dielectric film on a workpiece is disclosed, wherein the dielectric film has at least a first zone and a second zone where a thickness of the dielectric film in the first zone is greater than the second zone. The method comprises directing an ion beam having a thinning species toward the dielectric film, the ion beam providing a first dose in the first zone of the dielectric film and a second dose in the second zone of the dielectric film, the first dose being greater than the second dose, so as to reduce a difference in thickness of the dielectric film between the first zone and the second zone. In some embodiments, the first dose is at least twice the second dose. In some embodiments, the first dose is at least ten times the second dose. In some embodiments, the directing the ion beam is performed such that no ions are implanted into the second zone. In some embodiments, the thinning species comprises silicon. In some embodiments, the thinning species comprises a species heavier than silicon. In some embodiments, the thinning species comprises oxygen, fluorine, neon, or aluminum. In some embodiments, the dielectric film comprises silicon nitride, silicon oxide or silicon oxynitride. In some embodiments, the first zone comprises an annular ring disposed at an edge of the workpiece. In some embodiments, the first dose is 5E14 ions/cm² or greater, and the workpiece is maintained at a temperature greater than 300° C. during the directing. In some embodiments, the first dose is achieved by repeating a sequence of: directing the ion beam toward the first zone of the workpiece to provide a portion of the first dose; and rotating the workpiece. In some embodiments, the ion beam extends across the workpiece in a first direction, and the workpiece is translated in a second direction; and wherein a translation speed is slower when the ion beam is directed toward the first zone and the translation speed is faster when the ion beam is directed toward the second zone.

According to another embodiment, a method of adjusting a thickness of a dielectric film on a workpiece is disclosed, wherein the dielectric film has at least a first zone and a second zone where a thickness of the dielectric film in the first zone is greater than the second zone. The method comprises directing an ion beam having a thickening species toward the dielectric film, the ion beam providing a first dose in the first zone and a second dose in the second zone, the second dose being greater than the first dose, so as to reduce a difference in thickness of the dielectric film between the first zone and the second zone. In some embodiments, the second dose is at least twice the first dose. In some embodiments, the second dose is at least ten times the first dose. In some embodiments, the thickening species comprises helium. In some embodiments, the thickening species comprises hydrogen, carbon, boron, nitrogen. In some embodiments, the dielectric film comprises silicon nitride, silicon oxide or silicon oxynitride. In some embodiments, the second dose is 5E14 ions/cm² or greater, and the workpiece is maintained at a temperature greater than 300° C. during the directing. In some embodiments, the ion beam extends across the workpiece in a first direction, and the workpiece is translated in a second direction; and wherein a translation speed is slower when the ion beam is directed toward the second zone and the translation speed is faster when the ion beam is directed toward the first zone.

### BRIEF DESCRIPTION OF THE FIGURES

For a better understanding of the present disclosure, reference is made to the accompanying drawings, which are incorporated herein by reference and in which:

FIG. 1 shows a plot showing the thickness of a workpiece with a dielectric film;

FIG. 2 is an ion implantation system in accordance with one embodiment that may be used to perform the processes described herein;

FIG. 3 is an ion implantation system in accordance with another embodiment that may be used to perform the processes described herein;

FIG. 4 illustrates the scanning of the workpiece;

FIG. 5A shows a sequence that may be used to implant the outer zone of the workpiece;

FIGS. 5B-5C show two different translation speed profiles that may be used to implant the outer zone of the workpiece;

FIG. 6A shows a sequence that may be used to implant the inner zone of the workpiece;

FIG. 6B shows a translation speed profile that may be used to implant the inner zone of the workpiece;

FIG. 7 shows a workpiece with three zones having different thicknesses of dielectric film;

FIG. 8 shows a workpiece with a nonuniformity disposed at a random location.

### DETAILED DESCRIPTION

As described above, a uniform thickness of dielectric film is used in the creation of wavelength filters. However, dielectric films, as deposited or spun on, often have large variations in thickness.

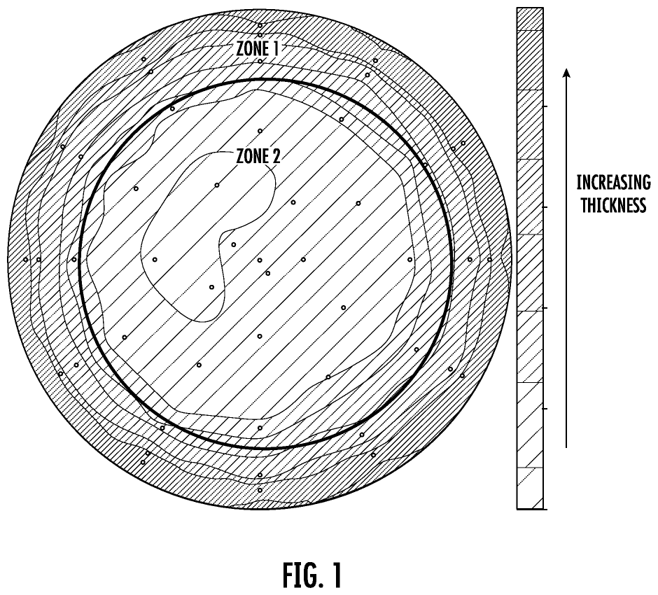

FIG. 1 shows a plot showing the thickness of a dielectric film as conventionally deposited. The dielectric film may be applied using physical vapor deposition (PVD), chemical vapor deposition (CVD), plasma enhanced CVD (PE-CVD) or spin coating. In this figure, the dielectric film comprises silicon nitride, although other dielectrics may be used. For example, silicon oxide (SiO₂) or silicon oxynitride (SiOₓN_{y}) may be used as the dielectric material. Note that, in this figure, the thickness at the edges of the workpiece is greater than the thickness of the dielectric film in the middle of the workpiece. In some embodiments, this difference may be 5 nanometers or more. In some embodiments, this difference may be 8 nanometers or more.

While FIG. 1 shows that the thickness is greater at the edge, this is not the only possibility. The non-uniform thickness in the dielectric film may have any shape. These other shapes may utilize more precise control of the dose, species and energy.

Further, it is noted that refractive index varies inversely with thickness. In other words, the thickest portions of the film also have the lowest refractive index. Conversely, the thinner portions of the film have the highest refractive index.

Based on the thickness of the dielectric film, the workpiece may be partitioned into different zones. These zones may be concentric circles. FIG. 1 shows two zones. The first zone, Zone 1, represents the thicker portion of the workpiece, and may be an annular ring proximate the outer edge of the workpiece. The second zone, Zone 2, represents the thinner portion of the workpiece, which is a circle at the center of the workpiece. Note that additional zones may also be created. For example, three zones may be created; a first zone where the film is thickest, a second zone where the film is thinnest, and a third zone where the film thickness is between these extremes. In some embodiments, the thickest portion of the workpiece may be near the center, where the thinner portion may be the annular ring near the outer edge of the workpiece.

Unexpectedly, it has been found that the implantation of certain species into the dielectric film, referred to as thinning species, actually reduce the thickness of the dielectric film. Surprising, these thinning species are not typically used for etching processes. For example, the implantation of silicon into a silicon nitride film may reduce the thickness of the film. This implantation also serves to increase the refractive index of the film. In one test, an implantation of silicon at a dose of 5E15 ions/cm² decreases the thickness of a silicon nitride film by roughly 70 angstroms. This implant also resulted in an increase of 0.06 in refractive index. An implantation of silicon at a dose of 1E16 ions/cm² roughly doubled both of these results. While silicon was used as the thinning species, it is noted that species which are heavier than silicon, such as phosphorus, xenon, antimony, germanium and argon, may also have this thinning effect. In some embodiments, oxygen, fluorine, neon and aluminum may also be thinning species. Of course, the relationship between dose and change in thickness may be different for each thinning species. Thus, in certain embodiments, the dose of the thinning species may be 5E14 ions/cm² or greater. In some embodiments, the dose of the thinning species may be 1E15 ions/cm² or greater. In some embodiments, the dose of the thinning species may be 1E16 ions/cm² or greater.

Additionally, it has been found that the implantation of other species, referred to as thickening species, actually increase the thickness of the dielectric film. For example, the implantation of helium into a silicon nitride film may increase the thickness of the film. This implantation also serves to decrease the refractive index of the film. In one test, an implantation of helium at a dose of 5E15 increases the thickness of a silicon nitride film by roughly 30 angstroms. This implant also resulted in a decrease of roughly 0.02 in refractive index. An implantation of helium at a dose of 1E16 increased the thickness of the dielectric film by almost 50 angstroms, while decreasing the refractive index by roughly 0.03. While helium is described as a thickening species, other species may also have this effect. For example, hydrogen, boron, carbon and nitrogen may also be thickening species. Thus, in certain embodiments, the dose of the thickening species may be 5E14 ions/cm² or greater. In some embodiments, the dose of the thickening species may be 1E15 ions/cm² or greater. In some embodiments, the dose of the thickening species may be 1E16 ions/cm² or greater.

In certain embodiments, these implants are performed at an elevated temperature, such as greater than 300° C. In certain embodiments, the implants may be performed at a temperature of 400° C. or greater.

Based on these findings, the uniformity of the film thickness is FIG. 1 may be improved. For example, if an implantation of a thinning species is performed in Zone 1, the thickness of this zone may be decreased, bringing it closer to the thickness of Zone 2. Alternatively, if an implantation of a thickening species is performed in Zone 2, the thickness of this zone may be increased, bringing it closer to the thickness of Zone 1. Of course, both implants may be performed. The variation in thickness may be reduced by 50% or more using this approach.

These implants can be performed using a plurality of different implantation systems.

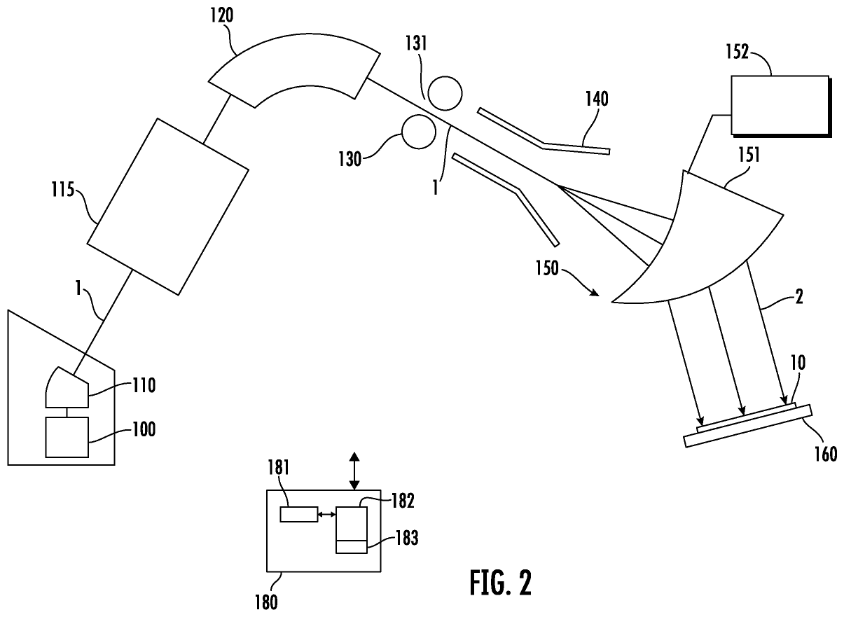

FIG. 2 shows a first implantation system, wherein a spot beam may be used for implanting ions into a workpiece using a spot beam according to one embodiment.

The spot beam ion implantation system includes an ion source 100 comprising a plurality of chamber walls defining an ion source chamber. In certain embodiments, the ion source 100 may be an RF ion source. In this embodiment, an RF antenna may be disposed against a dielectric window. This dielectric window may comprise part or all of one of the chamber walls. The RF antenna may comprise an electrically conductive material, such as copper. An RF power supply is in electrical communication with the RF antenna. The RF power supply may supply an RF voltage to the RF antenna. The power supplied by the RF power supply may be between 0.1 and 10 kW and may be any suitable frequency, such as between 1 and 100 MHz. Further, the power supplied by the RF power supply may be pulsed.

In another embodiment, a cathode is disposed within the ion source chamber. A filament is disposed behind the cathode and energized so as to emit electrons. These electrons are attracted to the cathode, which in turn emits electrons into the ion source chamber. This cathode may be referred to as an indirectly heated cathode (IHC), since the cathode is heated indirectly by the electrons emitted from the filament.

Other embodiments are also possible. For example, the plasma may be generated in a different manner, such as by a Bernas ion source, a capacitively coupled plasma (CCP) source, microwave or ECR (electron-cyclotron-resonance) ion source. The manner in which the plasma is generated is not limited by this disclosure.

One chamber wall, referred to as the extraction plate, includes an extraction aperture. The extraction aperture may be an opening through which the ions 1 generated in the ion source chamber are extracted and directed toward a workpiece 10. The extraction aperture may be any suitable shape. In certain embodiments, the extraction aperture may be oval or rectangular shaped.

Disposed outside and proximate the extraction aperture of the ion source 100 is a source filter 110.

Located downstream from the source filter 110 is a mass analyzer 120. An acceleration/deceleration column 115 is positioned between source filter 110 and mass analyzer 120. The mass analyzer 120 uses magnetic fields to guide the path of the extracted ions 1. The magnetic fields affect the flight path of ions according to their mass and charge. A mass resolving device 130 that has a resolving aperture 131 is disposed at the output, or distal end, of the mass analyzer 120. By proper selection of the magnetic fields, only those ions 1 that have a selected mass and charge will be directed through the resolving aperture 131. Other ions will strike the mass resolving device 130 or a wall of the mass analyzer 120 and will not travel any further in the system. The ions that pass through the mass resolving device 130 may form a spot beam.

The spot beam may then enter a scanner 140 which is disposed downstream from the mass resolving device 130. The scanner 140 causes the spot beam to be fanned out into a plurality of divergent ion beamlets. In other words, the scanner 140 creates diverging ion trajectory paths. The scanner 140 may be electrostatic or magnetic. The scanner 140 may comprise spaced-apart scan plates connected to a scan generator. The scan generator applies a scan voltage waveform, such as a sawtooth waveform, for scanning the ion beam in accordance with the electric field between the scan plates. Angle corrector 150 is designed to deflect ions in the scanned ion beam to produce scanned ion beam 2 having parallel ion trajectories, thus focusing the scanned ion beam. Specifically, the angle corrector 150 is used to alter the diverging ion trajectory paths into substantially parallel paths of a scanned ion beam 2. In particular, angle corrector 150 may comprise magnetic pole pieces 151 which are spaced apart to define a gap and a magnet coil (not shown) which is coupled to a power supply 152. The scanned ion beam 2 passes through the gap between the magnetic pole pieces 151 and is deflected in accordance with the magnetic field in the gap. The magnetic field may be adjusted by varying the current through the magnet coil. Beam scanning and beam focusing are performed in a selected plane, such as a horizontal plane.

The workpiece 10 is disposed on a movable workpiece holder 160.

In certain embodiments, the forward direction of the ion beam is referred to as the Z-direction, the direction perpendicular to this direction and horizontal may be referred to as the first direction or the X-direction, while the direction perpendicular to the Z-direction and vertical may be referred to as the second direction or the Y-direction. In this example, it is assumed that the scanner 140 scans the spot beam in the first direction while the movable workpiece holder 160 is translated in the second direction. The rate at which the scanner 140 scans the spot beam in the first direction may be referred to as beam scan speed or simply scan speed. The rate at which the movable workpiece holder 160 moves may be referred to as translation speed. In some embodiments, the platen is capable of rotation about the center of the workpiece, and may be referred to as a “roplat”.

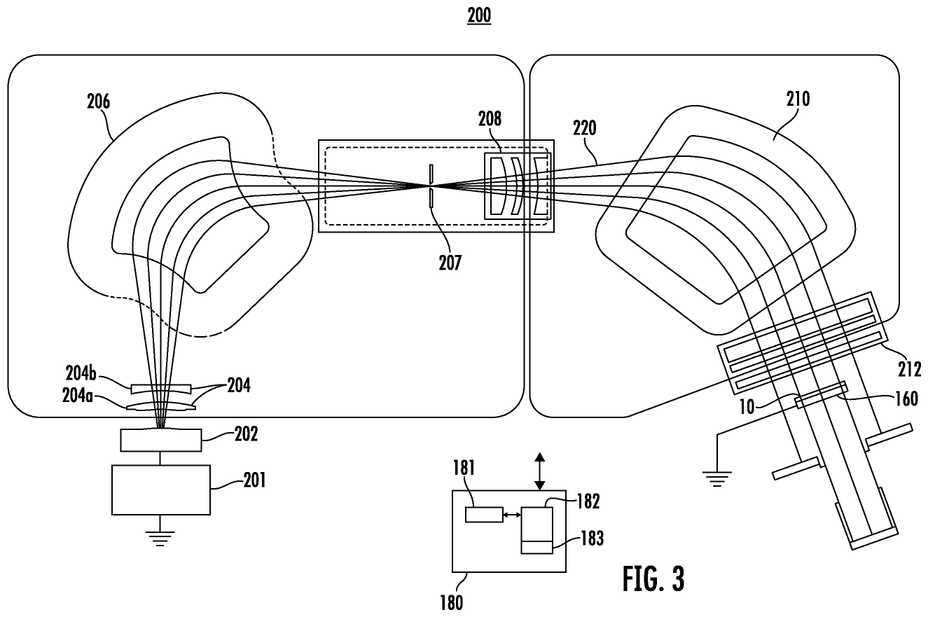

FIG. 3 shows a beamline ion implantation system 200 that utilizes a ribbon ion beam. As illustrated in the figure, the beamline ion implantation system 200 may comprise an ion source and a complex series of beam-line components through which an ion beam 220 passes. The ion source may comprise an ion source chamber 202 where ions are generated. The ion source may also comprise a power source 201 and an extraction electrode 204 disposed near the ion source chamber 202. The extraction electrodes 204 may include a suppression electrode 204a and a ground electrode 204b. Each of the ion source chamber 202, the suppression electrode 204a, and the ground electrode 204b may include an aperture. The ion source chamber 202 may include an extraction aperture (not shown), the suppression electrode may include a suppression electrode aperture (not shown), and a ground electrode may include a ground electrode aperture (not shown). The apertures may be in communication with one another so as to allow the ions generated in the ion source chamber 202 may pass through, toward the beam-line components.

The beamline components may include, for example, a mass analyzer 206, a mass resolving aperture 207, a first acceleration or deceleration (A1 or D1) stage 208, a collimator 210, and a second acceleration or deceleration (A2 or D2) stage 212. Much like a series of optical lenses that manipulate a light beam, the beamline components can filter, focus, and manipulate ions or ion beam 220. The ion beam 220 that passes through the beamline components may be directed toward the workpiece 10 that is mounted on a movable workpiece holder 160. The ion beam is much wider in the first direction and may be wider than the diameter of the workpiece 10. The workpiece 10 may be moved in one or more dimensions by a movable workpiece holder 160, sometimes referred to as a “roplat.” For example, the roplat may move in the second direction so that the entire workpiece 10 is exposed to the ribbon ion beam. The roplat may be configured to rotate the workpiece 10 about the center of the workpiece.

In both systems, a controller 180 is also used to control the implantation. The controller 180 has a processing unit 181 and an associated memory device 182. This memory device 182 contains the instructions 183, which, when executed by the processing unit, enable the system to perform the functions described herein. This memory device 182 may be any non-transitory storage medium, including a non-volatile memory, such as a FLASH ROM, an electrically erasable ROM or other suitable devices. In other embodiments, the memory device 182 may be a volatile memory, such as a RAM or DRAM. In certain embodiments, the controller 180 may be a general purpose computer, an embedded processor, or a specially designed microcontroller. The actual implementation of the controller 180 is not limited by this disclosure.

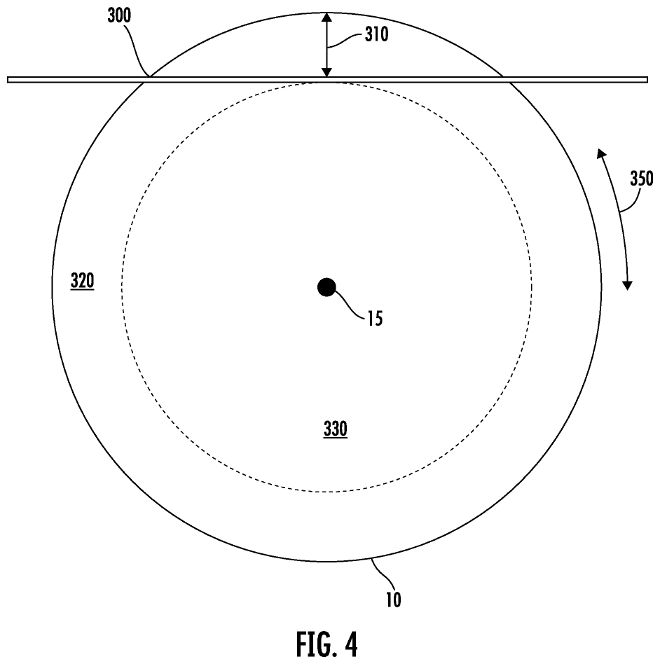

As described above and shown in FIG. 4, it may be advantageous to implant a species, such as a thinning species, into an outer zone 320 of the workpiece 10. To perform an implant that is only in this outer zone 320, the workpiece 10 may be translated by the movable workpiece holder 160 so as to be outside the path of the ion beam 300. The movable workpiece holder 160 then begins translating along the second direction such that the ion beam 300 strikes the workpiece 10. The movable workpiece holder 160 may only translate a small distance, such that only a portion of the workpiece 10 is exposed to the ion beam.

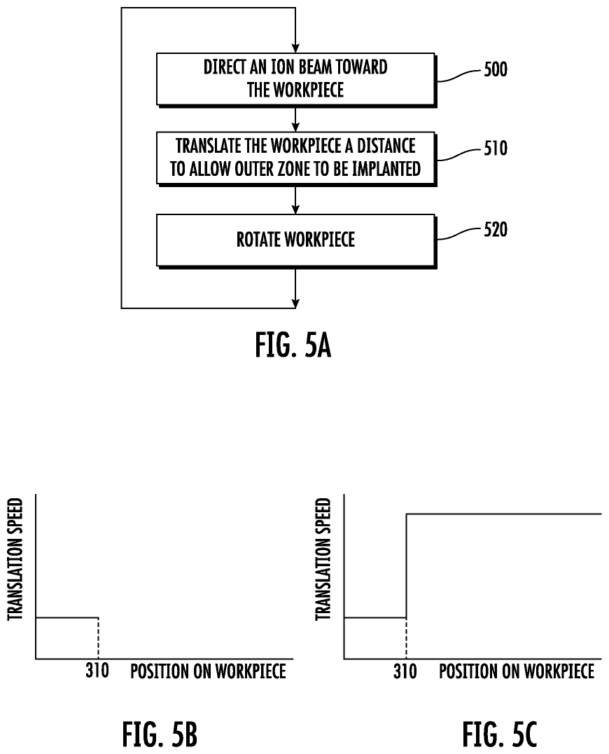

FIG. 5A shows the sequence of processes to implant the outer zone 320. As shown in Box 500, the ion beam 300 is directed toward the workpiece 10. Note that this ion beam 300 may be a scanned ion beam, as described in FIG. 2, or a ribbon ion beam, as described in FIG. 3. As shown in Box 510, the movable workpiece holder 160 may then translate a distance 310 so that only the desired portion of the workpiece 10 is implanted. At this point, the movable workpiece holder 160 may stop translating. In another embodiment, the translation speed of the movable workpiece holder 160 may increase so that the inner zone 330 of the workpiece 10 is exposed to the ion beam 300 for a shorter period of time. Thus, the total dose in the inner zone 330 is less than outer zone 320. FIGS. 5B and 5C show these two different translation speed profiles. FIG. 5B shows the translation speed where the movable workpiece holder 160 stops at distance 310. In some embodiments, the movable workpiece holder 160 may then move in the opposite direction to move the ion beam 300 off the workpiece 10. FIG. 5C shows the translation speed increase at distance 310 so that the rest of the workpiece receives a lower dose. In some embodiments, the outer zone 320 receives a first dose that is at least 2 times the second dose received in the inner zone 330. In some embodiments, the first dose in the outer zone 320 may be at least ten times the second dose received in the inner zone 330. Note that if desired, the translation speed may be slowed at a distance 310 before the bottom of the workpiece 10. As shown in Box 520, the workpiece 10 is then rotated about its center 15 as shown by arrow 350, and this process is repeated a plurality of times. In one embodiment, the workpiece is rotated 16 times, where each rotation is 22.5°. After this sequence is complete, the outer zone 320 is implanted with the first dose, while the inner zone 330 is either not implanted at all or implanted with a much smaller second dose of the thinning species. In some embodiments, the first dose may be 5E14 ions/cm² or greater. In certain embodiments, the first dose may be 1E15 ions/cm² or greater. In certain embodiments, the first dose may be 1E16 ions/cm² or greater. In some embodiments, the first dose may be 5E16 ions/cm² or less. In some embodiments, the first dose may be between 5E14 ions/cm² and 5E16 ions/cm².

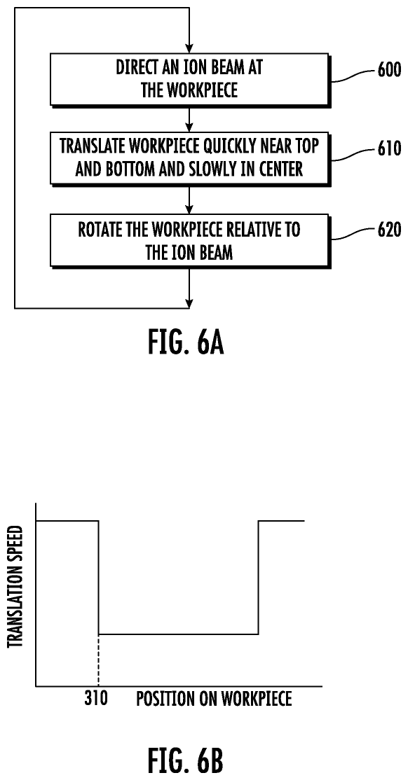

FIG. 6A shows a sequence that may be used to implant a species, such as a thickening species, in the inner zone 330. As shown in Box 600, the ion beam 300 is directed toward the workpiece 10. Note that this ion beam 300 may be a scanned ion beam, as described in FIG. 2, or a ribbon ion beam, as described in FIG. 3. As shown in Box 610, the movable workpiece holder 160 may then translate at a first speed until a distance 310 is reached. At this point, the translation speed decreases. For example, the second translation speed may be 3 to 10 times slower than the first speed. In this way, the inner zone 330 may receive a second dose that is at least 2 times the first dose in the outer zone 320. In some embodiments, the second dose in the inner zone 330 may be at least ten times the first dose in the outer zone 320. FIG. 6B shows this translation speed profiles. In this figure, FIG. 6B shows the translation speed profile where the translation speed decreases at distance 310 so that the center of the workpiece receives a higher dose than the outer edges. The translation speed is then increased at a distance 310 before the bottom of the workpiece 10. As shown in Box 620, the workpiece 10 is then rotated about its center 15 as shown by arrow 350, and this process is repeated a plurality of times. In one embodiment, the workpiece is rotated 16 times, where each rotation is 22.5°. After this sequence is complete, the inner zone 330 is implanted with the second dose, while the outer zone 320 implanted with a much smaller first dose of the thickening species. In some embodiments, the second dose may be 5E14 ions/cm² or greater. In certain embodiments, the second dose may be 1E15 ions/cm² or greater. In certain embodiments, the second dose may be 1E16 ions/cm² or greater. In some embodiments, the second dose may be 5E16 ions/cm² or less. In some embodiments, the second dose may be between 5E14 ions/cm² and 5E16 ions/cm².

Note that this sequence may be further enhanced if a scanned ion beam (see FIG. 2) is used. For example, for FIG. 6A, it is possible to vary the scan speed such that the scan speed is faster at the edges than it is in the center. Near the center of the workpiece, the scan speed profile may resemble the profile shown in FIG. 6B. Note that the scan speed profile would vary as the movable workpiece holder 160 is translated in the second direction. This is because the position of the edge of the workpiece 10 in the first direction (as well as the width of the inner zone 330) varies as a function of the second direction. For example, near the top of the workpiece 10 (before distance 310), the scan speed may be fast throughout, since there is no inner zone 330 at the top of the workpiece 10.

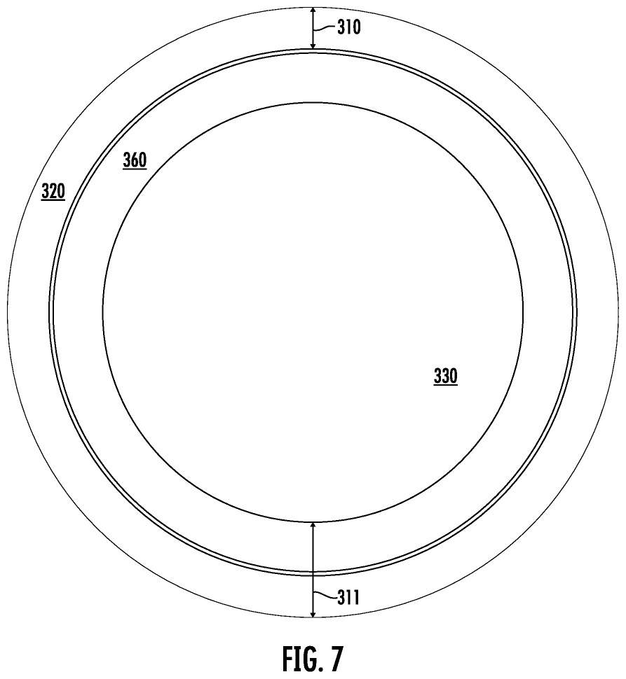

Note that the sequence of FIGS. 5A-5B may be adapted if there are more than two zones. For example, FIG. 7 shows an intermediate zone 360 between the inner zone 330 and the outer zone 320. The intermediate zone 360 may be an annular ring between the outer zone 320 and the inner zone 330. In this embodiment, it may be desirable to reduce the thickness of the intermediate zone 360, but to a lesser degree than the reduction in the outer zone 320. In one embodiment, the sequence of FIG. 5A may be performed several times to achieve this result. For example, the first time that the sequence is executed, the dose may be set to that desired for the intermediate zone 360. The translation speed profile is then established using distance 311 as the distance of interest. In other words, the implant is performed while the movable workpiece holder 160 is translated for a distance 311. At that point, the movable workpiece holder either stops (as shown in FIG. 5B) or speeds up (as shown in FIG. 5C). The workpiece is then rotated as described in FIG. 5A. Once completed, the intermediate zone 360 is properly dosed. The sequence of FIG. 5A is then repeated again using the distance 310 as the distance of interest. Further, the dose is set to the value needed to achieve the desired dose in the outer zone 320, in consideration of the dose that was already applied. The sequence is then repeated and a workpiece having three concentric zones, each implanted with a different dose, is created. Note that the two sequences may be performed in the opposite order if desired.

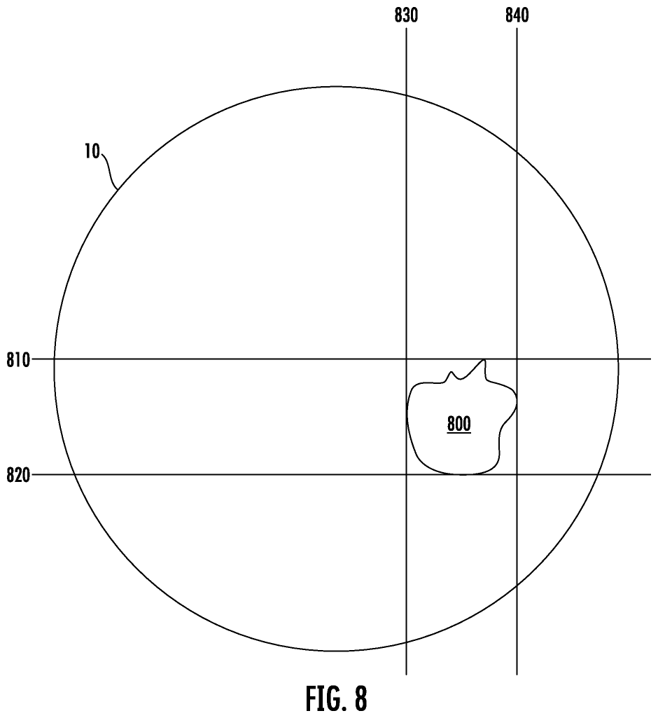

Further, the scanned ion beam (see FIG. 2) may allow corrections that are more complex than those described above. For example, as shown in FIG. 8, assume that there is a zone 800 of the film that is thicker than the rest of the film. Further, assume that this zone 800 is not symmetrically positioned on the workpiece 10 (in other words, it is not the entire inner zone or the outer zone). The thickness of this zone 800 may be reduced by implanting a thinning species into this zone 800. This may be done by having a first translation speed until position 810 is reached. At this point, a second translation speed, slower than the first translation speed, is used. The movable workpiece holder 160 returns to the first translation speed once position 820 is reached. This increases the dose that is supplied in the region of the workpiece 10 between position 810 and position 820. Further, when the movable workpiece holder 160 is between position 810 and position 820, the scan speed may be reduced in the region between position 830 and position 840. The changing of translation speed and scan speed allows the implantation to be mostly focused on zone 800. Thus, using this technique, any zone, regardless of shape or location, can be processed.

While the application discloses its use with waveguide filters, it is understood that the processes of processing the workpiece to make the thickness of the dielectric film more uniform may be applied to many other uses, such as dielectric films for Backend of Line (BEOL) stack, a hardmask for patterning and others.

The embodiments described above in the present application may have many advantages. Conventional deposition techniques typically create a dielectric film that is not uniform in thickness. In some cases, this nonuniformity may be 5 nanometers or more. The present approach reduces this nonuniformity by at least 50% without affecting the deposition process. Rather, ion implantation, which may be tightly controlled, is used to modify the thickness of the dielectric, by either increasing or decreasing its thickness. Further, this approach also helps makes the refractive index more uniform across the entirety of the dielectric film.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of adjusting a thickness of a dielectric film on a workpiece, the dielectric film having at least a first zone and a second zone where a thickness of the dielectric film in the first zone is greater than the second zone, comprising:
directing an ion beam having a thinning species toward the dielectric film, the ion beam providing a first dose in the first zone of the dielectric film and a second dose in the second zone of the dielectric film, the first dose being greater than the second dose, so as to reduce a difference in thickness of the dielectric film between the first zone and the second zone.

2. The method of claim 1, wherein the first dose is at least twice the second dose.

3. The method of claim 1, wherein the first dose is at least ten times the second dose.

4. The method of claim 1, wherein the directing the ion beam is performed such that no ions are implanted into the second zone.

5. The method of claim 1, wherein the thinning species comprises silicon.

6. The method of claim 1, wherein the thinning species comprises a species heavier than silicon.

7. The method of claim 1, wherein the thinning species comprises oxygen, fluorine, neon, or aluminum.

8. The method of claim 1, wherein the dielectric film comprises silicon nitride, silicon oxide or silicon oxynitride.

9. The method of claim 1, wherein the first zone comprises an annular ring disposed at an edge of the workpiece.

10. The method of claim 1, wherein the first dose is 5E14 ions/cm² or greater, and the workpiece is maintained at a temperature greater than 300° C. during the directing.

11. The method of claim 1, wherein the first dose is achieved by repeating a sequence of:
directing the ion beam toward the first zone of the workpiece to provide a portion of the first dose; and
rotating the workpiece.

12. The method of claim 1, wherein the ion beam extends across the workpiece in a first direction, and the workpiece is translated in a second direction; and wherein a translation speed is slower when the ion beam is directed toward the first zone and the translation speed is faster when the ion beam is directed toward the second zone.

13. A method of adjusting a thickness of a dielectric film on a workpiece, the dielectric film having at least a first zone and a second zone where a thickness of the dielectric film in the first zone is greater than the second zone, comprising:
directing an ion beam having a thickening species toward the dielectric film, the ion beam providing a first dose in the first zone and a second dose in the second zone, the second dose being greater than the first dose, so as to reduce a difference in thickness of the dielectric film between the first zone and the second zone.

14. The method of claim 13, wherein the second dose is at least twice the first dose.

15. The method of claim 13, wherein the second dose is at least ten times the first dose.

16. The method of claim 13, wherein the thickening species comprises helium.

17. The method of claim 13, wherein the thickening species comprises hydrogen, carbon, boron, nitrogen.

18. The method of claim 13, wherein the dielectric film comprises silicon nitride, silicon oxide or silicon oxynitride.

19. The method of claim 13, wherein the second dose is 5E14 ions/cm² or greater, and the workpiece is maintained at a temperature greater than 300° C. during the directing.

20. The method of claim 13, wherein the ion beam extends across the workpiece in a first direction, and the workpiece is translated in a second direction; and wherein a translation speed is slower when the ion beam is directed toward the second zone and the translation speed is faster when the ion beam is directed toward the first zone.
